(19) United States
(12) Patent Application Publication
(10) Pub. No.: US 2012/0119371 A1
(43) Pub. Date: May 17, 2012

(54) METHOD OF FABRICATING SEMICONDUCTOR DEVICE AND SEMICONDUCTOR DEVICE

(75) Inventors: Yasuhiro MATSUMOTO, Miyazaki (JP); Hiroki KUROKI, Miyazaki (JP); Toshifumi KOBE, Miyazaki (JP); Kiyohiko YOSHINO, Miyazaki (JP)

(73) Assignee: LAPIS SEMICONDUCTOR CO., LTD., Tokyo (JP)

(21) Appl. No.: 13/273,031

(22) Filed: Oct. 13, 2011

(30) Foreign Application Priority Data
Oct. 20, 2010 (JP) 2010-235643

(51) Int. Cl. H01L 23/485; H01L 21/768

(52) U.S. Cl. 257/773; 438/612; 257/E21.59; 257/E23.02

(57) ABSTRACT

There is provided a method of fabricating a semiconductor device including: forming an insulating film on a semiconductor substrate; forming a pad electrode on the insulating film; forming a protective film on the pad electrode; forming, on the protective film, a resist equipped with an open portion in a first region corresponding to part of the pad electrode; by using the resist as a mask, etching the protective film and etching the first region of part of the pad electrode to a predetermined depth; etching the protective film on a second region that surrounds the first region of the pad electrode; and removing the resist.

### CROSS-REFERENCE TO RELATED APPLICATION

This application is based on and claims priority under 35 USC 119 from Japanese Patent Application No. 2010-235643 filed on Oct. 20, 2010, the disclosure of which is incorporated by reference herein.

### BACKGROUND

1. Technical Field

The present invention relates to a method of fabricating a semiconductor device and a semiconductor device.

2. Related Art

Conventionally, it has been common for the surface of a pad electrode for external output of a semiconductor device to have no step and to be flat.

FIG. 3 shows a cross-sectional view of a conventional semiconductor device 100. As shown in FIG. 3, the semiconductor device 100 has a configuration where an intermediate insulating film 104, an underlying metal wire 106, an interlayer insulating film 108, a pad electrode 110, and a final protective film 112 are formed on a semiconductor substrate 102.

The underlying metal wire 106 and the semiconductor substrate 102 are interconnected by a contact 114, and the underlying metal wire 106 and the pad electrode 110 are interconnected by a contact 116.

Conventionally, as shown in FIG. 3, the surface of the pad electrode 110 that is exposed from the final protective film 112 is flat, so at the time of an electrical characteristic test for sorting out whether or not the semiconductor device is a reject, in a case where the force with which a test probe 118 is pressed against the pad electrode 110 is excessive as shown in FIG. 4, there have been cases where the test probe 118 slides on the surface of the pad electrode 110 and ends up contacting an end portion of the final protective film 112. At this time, there have been the problems that there are cases where cracks end up forming in the final protective film 112 and cases where the reliability of the semiconductor device 100 drops.

On the other hand, in a case where the force with which the test probe 118 is pressed against the pad electrode 110 is weak, there has been the problem that the contact resistance between the pad electrode 110 and the test probe 118 increases, rejects cannot be accurately sorted out, and the yield drops.

For this reason, Japanese Patent Application Laid-Open (JP-A) No. 2004-193299 and JP-A No. 60-198743 disclose semiconductor devices where a step is disposed in the surface of the pad electrode.

However, in the above-described related art, there has been the problem that it is necessary to form a film for forming a step in order to dispose the step and the number of fabrication steps increases. Further, in the case of not forming a film for forming a step, there has been the problem that it is necessary to etch the layer underlying the pad electrode to dispose a step in the underlying layer, and in either case the number of fabrication steps increases.

### SUMMARY

The present invention has been proposed in order to solve the aforementioned problems, and it is an object thereof to provide a semiconductor device fabrication method, and a semiconductor device, that can fabricate a semiconductor device where a step is disposed in a pad electrode without having to form a film for forming a step or having to etch a layer underlying the pad electrode to dispose a step in the underlying layer.

In order to achieve this object, a first aspect of the present invention provides a method of fabricating a semiconductor device including:

forming an insulating film on a semiconductor substrate;

forming a pad electrode on the insulating film;

forming a protective film on the pad electrode;

forming, on the protective film, a resist equipped with an open portion in a first region corresponding to part of the pad electrode;

by using the resist as a mask, etching the protective film and etching the first region of part of the pad electrode to a predetermined depth;

etching the protective film on a second region that surrounds the first region of the pad electrode; and

removing the resist.

According to this invention, the recessed portion is disposed in the pad electrode by etching the first region of part of the pad electrode to a predetermined depth, so it is not necessary to form a film for forming a step, and it is also not necessary to etch in order to dispose a step in the insulating film underlying the pad electrode. Moreover, after the first region of part of the pad electrode has been etched to the predetermined depth, the protective film in the second region surrounding the first region of the pad electrode is etched, so the semiconductor device can be given a structure where the wall surface of the recessed portion of the pad electrode is not continuous with the wall surface of the protective film. Because of this, when a test probe contacts the recessed portion, the test probe can be prevented from ending up contacting the wall surface of the protective film, and cracks can be prevented from ending up forming in the protective film.

A second aspect of the present invention provides a semiconductor device including:

a semiconductor substrate;

an insulating film that is formed on the semiconductor substrate;

a pad electrode that is formed on the insulating film and is equipped with a recessed portion; and

a protective film that is formed on the pad electrode in such a way that a region including the recessed portion and an area around the recessed portion is exposed.

According to this invention, the protective film is formed in such a way as to expose as far as the region of the environs around the recessed portion of the pad electrode, so the semiconductor device has a structure where the wall surface of the recessed portion of the pad electrode is not continuous with the wall surface of the protective film. Because of this, when a test probe contacts the recessed portion, the test probe can be prevented from ending up contacting the wall surface of the protective film, and cracks can be prevented from ending up forming in the protective film.

A third aspect of the present invention provides a semiconductor device including:

a semiconductor substrate;

an insulating film that is formed on the semiconductor substrate;

a pad electrode that is formed on the insulating film and is equipped with a first region of a first thickness, and a second region that has a second thickness thicker than the first thickness and surrounds the first region; and

a protective film that is equipped with an open portion in a region extending from the first region to part of the second region and is formed on the insulating film and the pad electrode.

According to this invention, the protective film, which is equipped with the open portion in a region extending from the first region of the first thickness of the pad electrode to part of the second region that has the second thickness thicker than the first thickness and surrounds the first region, is formed on the insulating film and the pad electrode, so the wall surface of the recessed portion of the pad electrode is not continuous with the wall surface of the protective film. Because of this, when a test probe contacts the recessed portion, the test probe can be prevented from ending up contacting the wall surface of the protective film, and cracks can be prevented from ending up forming in the protective film.

A fourth aspect of the present invention provides the semiconductor device according to the third aspect, further including a contact that interconnects the insulating film and the second region of the pad electrode.

In this way, because the contact is connected to the second region that is thicker than the first region, it becomes possible to reduce damage to the contact in a case where a test probe has been brought into contact with the recessed portion of the pad electrode.

According to the present invention, there is provided the effect that a semiconductor device where a step is disposed in a pad electrode can be fabricated without having to form a film for forming a step or having to etch a layer underlying the pad electrode to dispose a step in the underlying layer.

### BRIEF DESCRIPTION OF THE DRAWINGS

An exemplary embodiment of the present invention will be described in detail based on the following figures, wherein:

FIG. 1 is a cross-sectional view of a semiconductor device pertaining to the present invention;

FIG. 2A to FIG. 2D are diagrams showing steps for fabricating the semiconductor device pertaining to the present invention;

FIG. 3 is a cross-sectional view of a semiconductor device pertaining to a conventional example; and

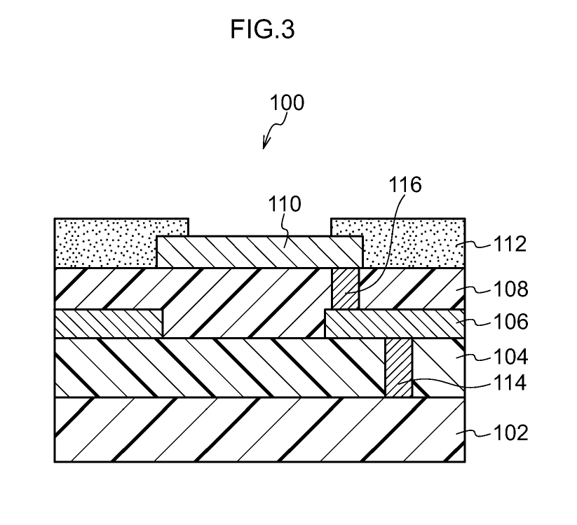

FIG. 4 is a diagram showing a case where a test probe has been brought into contact with a pad electrode of the semiconductor device pertaining to the conventional example.

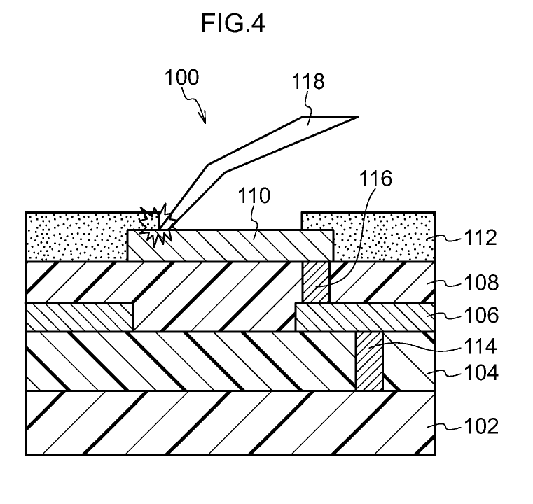

### DETAILED DESCRIPTION

An embodiment of the present invention will be described below.

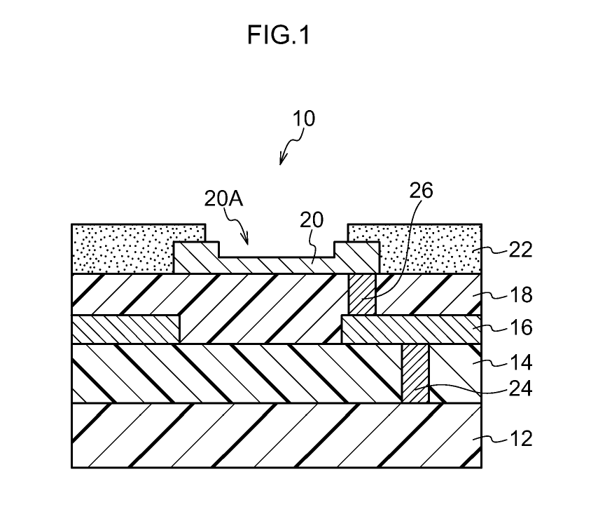

FIG. 1 shows a cross-sectional view of a semiconductor device 10 pertaining to the present embodiment. As shown in FIG. 1, the semiconductor device 10 has a configuration where an intermediate insulating film 14, an underlying metal wire 16, an interlayer insulating film 18, a pad electrode 20, and a final protective film 22 are formed on a semiconductor substrate 12.

The underlying metal wire 16 and the semiconductor substrate 12 are interconnected by a contact 24, and the underlying metal wire 16 and the pad electrode 20 are interconnected by a contact 26.

A recessed portion 20A is disposed in the pad electrode 20. That is, the pad electrode 20 is equipped with a first region of a first thickness and a second region that has a second thickness thicker than the first thickness and surrounds the first region, and the recessed portion 20A is configured by the first region and the second region. Because of this, a step is disposed in the pad electrode 20.

Further, the contact 26 is connected to the second region of the pad electrode 20. In this way, because the contact 26 is connected to the second region of the pad electrode 20, it becomes possible to reduce damage to the contact 26 in a case where a test probe has been brought into contact with the recessed portion 20A of the pad electrode 20.

The final protective film 22 is equipped with an open portion in a region extending from the first region of the pad electrode 20 to part of the second region, and the final protective film 22 is formed on a region of the interlayer insulating film 18 and part of the second region of the pad electrode 20. That is, the final protective film 22 is formed in such a way that a region including the recessed portion 20A of the pad electrode 20 and the environs around the recessed portion 20A is exposed and in such a way that the other region is not exposed.

Next, a method of fabricating the semiconductor device 10 shown in FIG. 1 will be described.

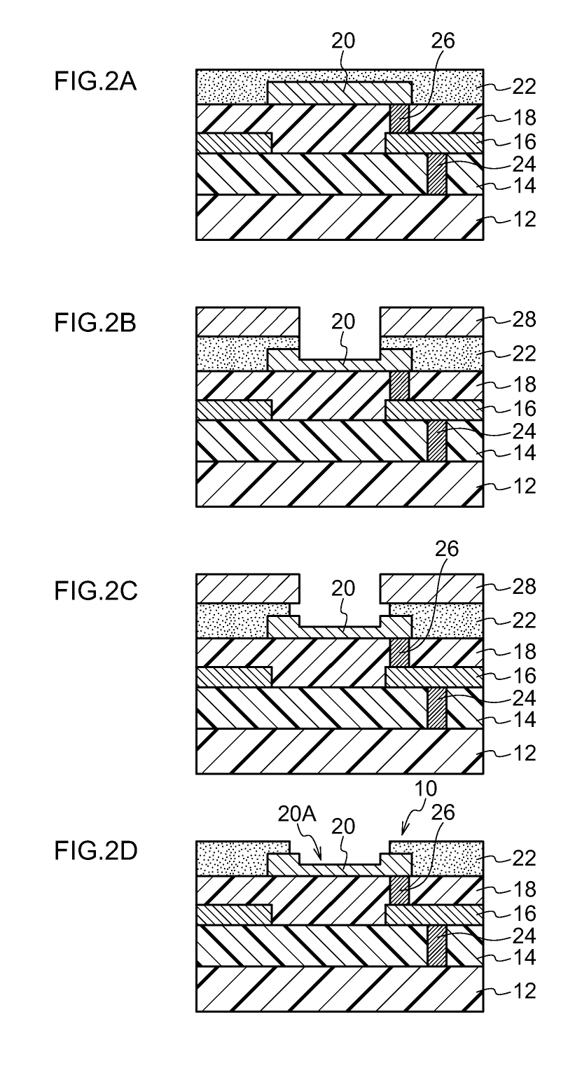

First, as shown in FIG. 2A, a desired element is formed on the semiconductor substrate 12, and the intermediate insulating film 14, the contact 24, and the underlying metal wire 16 are formed thereon.

Next, the interlayer insulating film 18 and the contact 26 are formed on the underlying metal wire 16, and the pad electrode 20 is formed thereon. Then, the final protective film 22 is formed on the pad electrode 20. Various publicly-known techniques can be used for these steps.

Next, a publicly-known photolithographic technique and etching technique are used to form on the final protective film 22 a resist 28 of a pattern corresponding to the shape of the recessed portion 20A of the pad electrode 20. That is, the resist 28 is formed on a region outside the region corresponding to the recessed portion 20A in such a way that the final protective film 22 and the pad electrode 20 in the region corresponding to the recessed portion 20A are etched.

Then, as shown in FIG. 2B, the resist 28 is used as a mask to etch the region where the resist 28 is not formed, that is, the final protective film 22 and the pad electrode 20 in the region corresponding to the recessed portion 20A. At this time, the pad electrode 20 is etched to a predetermined depth in such a way as to not penetrate the pad electrode 20.

An etching gas such as CHF₃ or CF₄/H₂, for example, is used to etch the final protective film 22. Further, an etching gas such as Cl₂ or BCl₃, for example, is used to etch the pad electrode 20.

Next, as shown in FIG. 2C, the resist 28 is left as is and an etching gas such as CHF₃ or CF₄/H₂ is used to etch just the final protective film 22 and remove the final protective film 22 as far as the region of the environs around the recessed portion 20A of the pad electrode 20.

Then, as shown in FIG. 2D, the resist 28 is removed using a publicly-known method, whereby the semiconductor device 10 is fabricated.

In this way, in the present embodiment, the recessed portion 20A is disposed in the pad electrode 20 by etching the pad electrode 20 to a predetermined depth, so it is not necessary to form a film for forming a step, and it is also not necessary to etch in order to dispose a step in the interlayer insulating film 18 underlying the pad electrode 20.

Moreover, after the pad electrode 20 has been etched to the predetermined depth, just the final protective film 22 is etched in such a way that the region of the environs around the recessed portion 20A is exposed, so the semiconductor device 10 can be given a structure where the wall surface of the recessed portion 20A of the pad electrode 20 is not continuous with the wall surface of the final protective film 22. Because of this, when a test probe contacts the recessed portion 20A, the test probe can be prevented from ending up contacting the wall surface of the final protective film 22, and cracks can be prevented from ending up forming in the final protective film 22.

What is claimed is:

1. A method of fabricating a semiconductor device comprising:
forming an insulating film on a semiconductor substrate;
forming a pad electrode on the insulating film;
forming a protective film on the pad electrode;
forming, on the protective film, a resist equipped with an open portion in a first region corresponding to part of the pad electrode;
by using the resist as a mask, etching the protective film and etching the first region of part of the pad electrode to a predetermined depth;
etching the protective film on a second region that surrounds the first region of the pad electrode; and
removing the resist.

2. A semiconductor device comprising:
a semiconductor substrate;
an insulating film that is formed on the semiconductor substrate;
a pad electrode that is formed on the insulating film and is equipped with a recessed portion; and
a protective film that is formed on the pad electrode in such a way that a region including the recessed portion and an area around the recessed portion is exposed.

3. A semiconductor device comprising:
a semiconductor substrate;
an insulating film that is formed on the semiconductor substrate;
a pad electrode that is formed on the insulating film and is equipped with a first region of a first thickness, and a second region that has a second thickness thicker than the first thickness and surrounds the first region; and
a protective film that is equipped with an open portion in a region extending from the first region to part of the second region and is formed on the insulating film and the pad electrode.

4. The semiconductor device according to claim 3, further comprising a contact that interconnects the insulating film and the second region of the pad electrode.
